(19) United States
(12) Patent Application Publication
(10) Pub. No.: US 2009/0029064 A1
(43) Pub. Date: Jan. 29, 2009

(54) Apparatus and method for making nanoparticles using a hot wall reactor

(76) Inventors: Carlton Maurice Truesdale, Corning, NY (US); Joseph Marc Whalen, Halifax (CA)

Correspondence Address: CORNING INCORPORATED, SP-TI-3-1, CORNING, NY, 14831, US

(21) Appl. No.: 11/881,119

(22) Filed: Jul. 25, 2007

(51) Int. Cl. C23C 16/511; C23C 16/54

(52) U.S. Cl. 427/544; 118/715; 118/723 R; 118/723 MW; 977/891; 977/788

(57) ABSTRACT

An apparatus utilizing a hot wall reactor and methods for making nanoparticles are described. The nanoparticles can be collected in bulk or deposited onto a base substrate. The hot wall reactor utilizes gas-phase synthesis to produce nanoparticles. Inorganic nanoparticles deposited onto a substrate are useful, for example, for biological applications, for example, biomolecule attachment such as DNA, RNA, protein and the like. The inorganic porous substrates are also useful for cell growth applications.

### BACKGROUND

1. Field of the Invention

The present invention relates generally to an apparatus and methods for making nanoparticles and more particularly to an apparatus for making nanoparticles that comprises a hot wall reactor and methods of making porous substrates utilizing nanoparticles deposited onto a substrate.

2. Technical Background

Over the years, there has been rapid progress in the areas of electronics, materials science, and nanoscale technologies resulting in, for example, smaller devices in electronics, advances in fiber manufacturing and new applications in the biotechnology field. The ability to generate and collect increasingly smaller, cleaner and more uniform particles is necessary in order to foster technological advances in areas which utilize small particulate matter. The development of new, efficient and adaptable ways of producing small particulate matter and subsequently collecting or depositing the small particulate matter onto a substrate becomes more and more advantageous.

The size of a particle often affects the physical and chemical properties of the particle or material comprising the particle. For example, optical, mechanical, biochemical and catalytic properties often change when a particle has cross-sectional dimensions smaller than 200 nanometers (nm). When particle sizes are reduced to smaller than 200 nm, these smaller particles of an element or a material often display properties that are quite different from those of larger particles of the same element or material. For example, a material that is catalytically inactive in the macroscale can behave as a very efficient catalyst when in the form of nanoparticles.

The aforementioned particle properties are valuable in many technology areas. For example, in optical fiber manufacturing, the generation of substantially pure silica and germania soot particles from impure precursors in a particular size range (about 5-300 nm) has been key in providing optical preforms capable of producing high purity optical fiber. Also, in the field of pharmaceuticals, the generation of particles having certain predetermined properties is advantageous in order to optimize, for example, in vivo delivery, bioavailability, stability of the pharmaceutical and physiological compatibility. The optical, mechanical, biochemical and catalytic properties of particles are closely related to the size of the particles.

Porous microstructures are of great interest to many research and commercial areas. Three-dimensional structures made from nanoparticles provide optimum surface area. Enhanced surface area is an enabling physical property for many applications, such as custom spotted microarrays, high display of surface area for catalysis, high display of luminescent elements and the like. Conventional methods of producing enhanced surface area, such as the method described in PCT Publication No. WO0116376A1 and commonly owned US Patent Application Publication Nos. 2003/0003474 and 2002/0142339, the disclosures of which are incorporated herein by reference in their entirety, use ball milled Corning 1737™ glass particles of size range from 0.5 μm to 2 μm. These ball milled particles are sintered onto Corning 1737™ glass substrates. Deposits of nanoparticles provide optimum surface area. However, particles in this nanometer size range are difficult to produce and deposit onto a substrate.

The conventional ball milling processes for manufacturing slides for use in the manufacture of microarrays have the following disadvantages: lot to lot variability between ball milled preparations of 1737™ microparticles, broad heterogeneous particle size distributions, requirement for post processing deposition of the ball milled microparticles by either tape casting or screen printing, particle sizes are especially large and do not yield optimum nanoparticle surface areas, screen printing has been shown to yield missing spot effects on microarrays due to irregular surface patterns and limitation of the process to 1737™ glasses.

Particle generators such as aerosol reactors have been developed for gas-phase nanoparticle synthesis. Examples of these aerosol reactors include flame reactors, tubular furnace reactors, plasma reactors, and reactors using gas-condensation methods, laser ablation methods, and spray pyrolysis methods.

In particular, hot wall tubular furnace reactors have proven adept for soot particle generation for silica preform production in optical fiber manufacturing, for example, those described in commonly owned US Patent Application Publications 2004/0187525 and 2004/0206127, the disclosures of which are incorporated herein by reference in their entirety.

Further, conventional methods of producing aerosol particles, for example those described in commonly owned US Patent Application Publications 2004/0187525 and 2004/0206127 utilize SiCl₄ as a precursor to produce SiO₂ powder on combustion. Thus, chlorine abatement would be necessary in a manufacturing process.

It would be advantageous to have an apparatus and a method for producing particles in the nanometer size range by gas-phase synthesis thus minimizing the size variation and composition variation evident in conventional ball milling processes.

### SUMMARY

The apparatus for generating nanoparticles and methods for producing nanoparticles of the present invention as described herein, address the above-mentioned disadvantages of the conventional ball milling methods and conventional aerosol particle generating methods, in particular, when the desired particles are dimensionally in the nanometer range.

In one embodiment, an apparatus for generating aerosol particles is disclosed. The apparatus comprises an atomizer comprising a reservoir, a nozzle adapted to receive a flow of solution from the reservoir, and a pump for providing a flow of solution from the reservoir through the nozzle; and a hot wall reactor adapted to receive a spray of aerosol droplets from the nozzle of the atomizer.

In another embodiment, a method for making nanoparticles is disclosed. The method comprises providing a solution comprising nanoparticle precursors and a solvent; atomizing the solution to form aerosol droplets; and passing the aerosol droplets through a hot wall reactor under conditions sufficient to generate nanoparticles.

Additional features and advantages of the invention will be set forth in the detailed description which follows, and in part will be readily apparent to those skilled in the art from the description or recognized by practicing the invention as described in the written description and claims hereof, as well as the appended drawing.

It is to be understood that both the foregoing general description and the following detailed description are merely exemplary of the invention, and are intended to provide an overview or framework to understanding the nature and character of the invention as it is claimed.

The accompanying drawing is included to provide a further understanding of the invention, and is incorporated in and constitutes a part of this specification. The drawing illustrates one or more embodiment(s) of the invention and together with the description serves to explain the principles and operation of the invention.

### BRIEF DESCRIPTION OF THE DRAWING

The invention can be understood from the following detailed description either alone or together with the accompanying drawing FIGURE.

FIG. 1 is a schematic of the apparatus according to one embodiment of the present invention.

### DETAILED DESCRIPTION

Reference will now be made in detail to various embodiments of the invention, an example of which is illustrated in the accompanying drawing.

As used herein:

the term “susceptor” refers to any material capable of generating heat when acted upon by energy from an energy source.

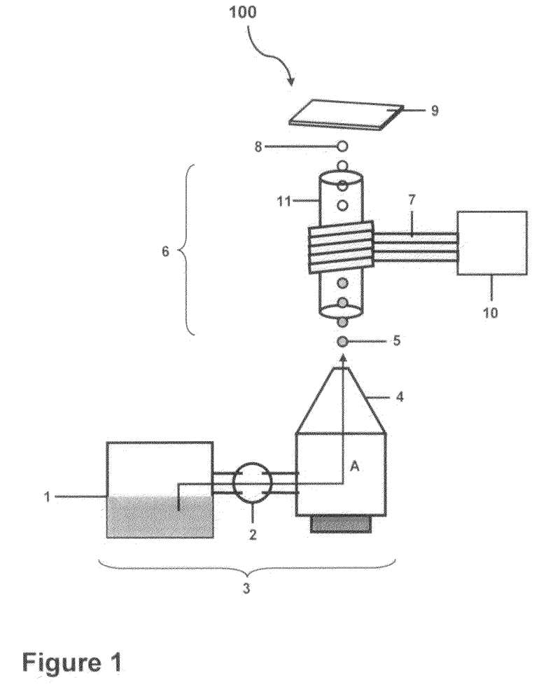

FIG. 1 is a schematic of an apparatus 100 according to one embodiment. The apparatus comprises an atomizer 3 comprising a reservoir 1, a nozzle 4 adapted to receive a flow of solution from the reservoir, and a pump 2 for providing a flow of solution, shown by arrow A, from the reservoir through the nozzle; and a hot wall reactor 6 adapted to receive a spray of aerosol droplets 5 from the nozzle of the atomizer.

According to some embodiments, as shown in FIG. 1, the hot wall reactor 6 comprises a tubular, glass wall 11, a susceptor 7 capable of generating heat when acted upon by energy and transferring heat to the interior space defined by the glass wall; and an energy source 10 for providing the energy to the susceptor. In other embodiments, the material of the walls of the hot wall reactor is selected from a ceramic, a quartz, a glass/ceramic, a metal and combinations thereof.

In some embodiments, the energy source is a source of electromagnetic radiation, for example, an induction heating system, a dielectric heating system, or a microwave heating system. Exemplary hot wall reactors are described in commonly owned U.S. patent application Ser. No. 11/502,286, the disclosure of which is incorporated herein by reference in its entirety. Further, exemplary susceptor materials, energy sources and combinations thereof are described in U.S. patent application Ser. No. 11/502,286.

Induction particle generators are examples of hot wall reactors using an inductive heating system to heat the susceptor(s) which are the reactor walls or are within the reactor walls, or as shown in FIG. 1, which are outside of the reactor walls. Examples of such induction particle generators are described in commonly owned US Patent Application Publications 2004/0187525 and 2004/0206127, the disclosures of which are incorporated herein by reference in their entirety, and may be used to produce a flow of aerosol containing aerosol particles dimensionally in the nanometer range.

According to another embodiment, a method for making nanoparticles is disclosed. The method comprises providing a solution comprising nanoparticle precursors and a solvent; atomizing the solution to form aerosol droplets; and passing the aerosol droplets through a hot wall reactor under conditions sufficient to generate nanoparticles.

A solution, for example, aqueous or organic, is prepared which comprises compounds that correspond to the composition of cations found in the desired nanoparticles.

According to one embodiment, the solvent comprises an alcohol. In other embodiments, the solvent can be selected from methanol, ethanol, propanol, methoxy-alcohols, alkoxy-alcohols, hydrocarbon solvents, ketones, ethers, methyl-ethyl ether, carboxylic acids, esters, water and combinations thereof.

Solvents, for example, methanol, ethanol, propanol, higher alcohols (including all possible isomers of carbon chains) or mixtures thereof can be used to dissolve metal-organic compounds to form homogeneous solutions. In other solvents, for example, water or co-solvents of water mixed with alcohols or other polar organic solvents (e.g., ketones, carboxylic acids, esters, and ethers), metals will be dissolved as salts such as nitrates, sulfates, halides and the like.

An example of the method is the dissolution of Si(OCH₂CH₃)₄, B(OCH₂CH₃)₃, Al(OCH₂CH₃)₃, Ca(OCH₂CH₃)₂, Mg(OCH₂CH₃)₂ Sr(OCH₂CH₃)₂ and Ba(OCH₂CH₃)₂ in ethanol in appropriate amounts such that nanoparticle precursors, in this example, the metal oxide composition after gas-phase synthesis corresponds to that of the base substrate on which the nanoparticles are deposited.

The solution is then atomized to form aerosol droplets. In one embodiment, the aerosol droplets have a mean droplet size of from 5 microns to 20 microns in diameter. A variety of atomization technologies are commercially available, for example, an air-assisted atomizer, for example, Schlick Atomizing Technologies model 970 S4.

The aerosol droplets are then passed through a hot wall reactor under conditions sufficient to generate nanoparticles. Aerosol droplets having a mean droplet size of from 5 microns to 20 microns in diameter are easily entrained in a carrier gas passing through the hot wall reactor. In one embodiment, the carrier gas is, for example, air from the atomizer. In other embodiments, oxygen, nitrogen, argon or a combination thereof can be introduced into the hot wall reactor. The carrier gas can be introduced, in one embodiment, at the entrance of the hot wall reactor with the aerosol droplets or in other embodiments, the carrier gas can be introduced through ports located along the length of the hot wall reactor. There can be a plurality of ports for the introduction of carrier gases or precursor materials. The hot wall reactor could be, for example, any heated tubular reactor, for example, an induction particle generator.

Temperatures in the interior space of the hot wall reactor, for example, a tubular hot wall reactor, in the range of from 400° C. to 700° C., for example, from 450° C. to 550° C., are sufficient for the conversion of the aerosol droplets into multicomponent oxide particles for the 1737™ glass and Eagle 2000™ glass compositions. Temperatures can be adjusted, for example, in the range of from room temperature to in excess of 1600° C. to facilitate the delivery of specific predetermined nanoparticle sizes and morphology and can be adjusted depending upon the nanoparticle precursors and desired resulting nanoparticles after gas-phase synthesis.

The nanoparticles after gas-phase synthesis can have a mean diameter of from 1 nanometer to 500 nanometers, for example, from 1 nanometer to 300 nanometers, for example, from 1 nanometer to 200 nanometers, for example, from 1 nanometer to 100 nanometers, for example, from 1 nanometer to 50 nanometers. The mean diameter of the nanoparticles can be adjusted by adjusting process conditions, for example, the concentration of the nanoparticle precursors in the solution, the flow rate of the solution, the flow rate of the aerosol droplets, the concentration of the nanoparticle precursors in the flow of aerosol, the temperature of the interior space of the hot wall reactor and combinations thereof.

In one embodiment, the method of making nanoparticles comprises collecting the nanoparticles. The nanoparticles can either be collected in bulk or deposited onto a base substrate. If the nanoparticles are being collected in bulk, a collection container, for example, a tube, a beaker, a flask, a cup, or the like in which the nanoparticles will collect can be placed in proximity to the exit of the hot wall reactor. The collection container can comprise materials, for example, a polymer, a metal, a glass, a glass/ceramic or combinations thereof.

As shown in FIG. 1, the nanoparticles 8 can be deposited onto a base substrate 9. According to some embodiments, the base substrate comprises a material selected from a polymer, a glass, a ceramic, a glass/ceramic, a metal and combinations thereof. Exemplary base substrate compositions in weight percent are 1737™ glass (SiO₂ 58.69, Al₂O₃ 16.71, B₂O₃ 8.48, MgO 0.75, CaO 4.19, SrO 1.92, BaO 9.27) and Eagle 2000™ glass (SiO₂ 64.16, Al₂O₃ 16.56, B₂O₃ 10.47, MgO 0.12, CaO 7.80, SrO 0.81, BaO 0.07). Note that fining agents, for example, arsenic or antimony are not needed since a fining process subsequent to deposition is not required.

According to one embodiment, the nanoparticle coated substrate is then fired or sintered to promote adhesion of the nanoparticles to the base substrate.

Conventional LCD glass compositions contain toxic Sb₂O₃ (1.85 wt % in 1737™) and As₂O₃ (0.9 wt % in Eagle 2000™). Ball milling these glasses to powders results in increased processing costs due, in part, to additional safety precautions and waste management needed in the handling of these materials. The 1737™ and Eagle™ compositions can be prepared by the methods disclosed herein without the addition of arsenic or antimony, since these materials are added for glass melt fining only and are not necessary in the method of the present invention. Arsenic and antimony fining agents do not significantly affect relevant bulk properties such as coefficient of thermal expansion (CTE) and softening point of the resulting glass.

The particle size, purity, surface area etc. of the nanoparticles produced by the apparatus and methods described by the present invention, for example, utilizing a hot wall reactor, for example, an induction soot gun or particle generator is more uniform than those produced by the above-mentioned conventional ball milling methods. The induction soot gun or particle generator is known to produce smaller particles (surface area advantage) higher purity (does not contain the zirconium contamination observed in ball milling) and is more homogeneous and reproducible than the ball milled particles. For these reasons, inorganic porous substrates, for example, SiO₂ nanoparticles deposited onto 1737™ slides are useful for manufacturing DNA/protein assays.

Microarrays utilizing the inorganic porous substrates made using the methods of the present invention should possess better signal-to-noise than the microarrays utilizing the conventional ball milled 1737™ glass particles deposited onto 1737™ microscope slides.

The apparatus and methods of the present invention possess an additional advantage, in that, typically for gas-phase synthesis of glass particles, precursors which readily volatilize to a gaseous phase (e.g., SiCl₄) are needed in order to produce the desired nanoparticles using a hot wall reactor. Several of the components of 1737™ glass do not have precursors which can be volatilized and therefore the apparatus and methods described herein have the advantage of using a solution, wherein the composition of the solution matches the composition of the aerosol which matches the composition of the resulting nanoparticles. Thus, chlorine abatement is not necessary in a manufacturing process, since by using metal-organic precursors as described herein, the only gaseous byproducts are H₂O and CO₂, in that instance.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. An apparatus for generating aerosol particles comprising:
an atomizer comprising a reservoir, a nozzle adapted to receive a flow of solution from the reservoir, and a pump for providing a flow of solution from the reservoir through the nozzle; and a hot wall reactor adapted to receive a spray of aerosol droplets from the nozzle of the atomizer.

2. The apparatus of claim 1, wherein the hot wall reactor comprises a susceptor capable of generating heat when acted upon by energy; and an energy source for providing the energy to the susceptor.

3. The apparatus of claim 2, wherein said energy source is a source of electromagnetic radiation.

4. The apparatus of claim 3, wherein the source of electromagnetic radiation is an induction heating system.

5. The apparatus of claim 3, wherein the source of electromagnetic radiation is a dielectric heating system.

6. The apparatus of claim 3, wherein the source of electromagnetic radiation is a microwave heating system.

7. A method for making nanoparticles, the method comprising:
providing a solution comprising nanoparticle precursors and a solvent; atomizing the solution to form aerosol droplets; and passing the aerosol droplets through a hot wall reactor under conditions sufficient to generate nanoparticles.

8. The method according to claim 7, further comprising collecting the nanoparticles.

9. The method according to claim 8, wherein collecting the nanoparticles comprises depositing the nanoparticles onto a base substrate.

10. The method according to claim 7, wherein the aerosol droplets have a mean droplet size of from 5 microns to 20 microns in diameter.

11. The method according to claim 7, wherein the nanoparticle precursors comprise glass precursors.

12. The method according to claim 11, wherein the glass precursors comprise Si(OCH₂CH₃)₄, B(OCH₂CH₃)₃, Al(OCH₂CH₃)₃, Ca(OCH₂CH₃)₂, Mg(OCH₂CH₃)₂, Sr(OCH₂CH₃)₂, Ba(OCH₂CH₃) 2 or combinations thereof.

13. The method according to claim 7, wherein the solvent comprises an alcohol.

14. The method according to claim 7, wherein the solvent is selected from methanol, ethanol, propanol, methoxy-alcohols, alkoxy-alcohols, hydrocarbon solvents, ketones, ethers, methyl-ethyl ether, carboxylic acids, esters, water and combinations thereof.

15. The method according to claim 7, wherein the nanoparticles have a mean diameter of from 1 nanometer to 500 nanometers.

16. The method according to claim 15, wherein the nanoparticles have a mean diameter of from 1 nanometer to 300 nanometers.

17. The method according to claim 16, wherein the nanoparticles have a mean diameter of from 1 nanometer to 200 nanometers.

18. The method according to claim 17, wherein the nanoparticles have a mean diameter of from 1 nanometer to 100 nanometers.

19. The method according to claim 18, wherein the nanoparticles have a mean diameter of from 1 nanometer to 50 nanometers.

20. The method according to claim 9, wherein the base substrate comprises a material selected from a polymer, a glass, a ceramic, a glass/ceramic, a metal and combinations thereof.
